(19) United States
(12) Patent Application Publication
(10) Pub. No.: US 2022/0290307 A1
(43) Pub. Date: Sep. 15, 2022

(54) MULTI-LAYER METAL ARTICLE AND METHOD OF MAKING THE SAME

(71) Applicant: Reut RINGEL, Long Island City, NY (US)

(72) Inventor: Reut RINGEL, Long Island City, NY (US)

(21) Appl. No.: 17/635,093

(22) PCT Filed: Aug. 11, 2020
(86) PCT No.: PCT/US2020/045702

§ 371 Date: Feb. 14, 2022

Related U.S. Application Data
(60) Provisional application No. 62/886,316, filed on Aug. 13, 2019.

(51) Int. Cl. C23C 28/02; C23C 28/00

(52) U.S. Cl. CPC C23C 28/025; C23C 28/021; C23C 28/321; C23C 28/341; C23C 28/3225

(57) ABSTRACT

The multi-layer metal article (10) includes a metal base (12) formed from a first metal and at least one interlayer (14) formed on an upper surface (18) of the metal base (12). The at least one interlayer (14) is formed from a second metal having a greater hardness than a hardness of the first metal, thus increasing the hardness of the overall multi-layer metal article (10) when compared against the hardness of just the metal base (12). An outer coating layer (16) may then be coated on an upper surface (20) of the at least one interlayer (14). As a non-limiting example, the outer coating layer (16) may be a scratch-resistant material, thus increasing both the hardness and scratch resistance of the overall multi-layer metal article (10) when compared against those of just the metal base (12). The outer coating layer (16) may be transparent, partially transparent or opaque.

### CROSS-REFERENCE TO RELATED APPLICATION

This application claims the benefit of U.S. Provisional Patent Application No. 62/886,316, filed on Aug. 13, 2019.

### TECHNICAL FIELD

The disclosure of the present patent application relates to multi-layer metal articles, such as articles of jewelry and the like, and particularly to multi-layer metal articles including a metal base, at least one interlayer formed on the metal base, and an outer coating layer, where the at least one interlayer has a greater hardness than the metal base.

### BACKGROUND ART

Jewelry, decorative articles and the like are often formed from precious metals, such as gold, silver, platinum and the like. These metals, particularly when of high purity, tend to be soft metals, thus making them highly susceptible to scratches, dents and other damage. Although such metals may be mixed with other metals (i.e., forming alloys) or other materials to increase their hardness, such modifications to the base material change its overall properties, from its weight to its ability to be shaped or sculpted. Further, particularly with regard to jewelry, buyers typically want the article to be formed from a particular material of high purity, rather than an alloy or hybrid of that material. Thus, a multi-layer metal article and a method of making the same solving the aforementioned problems are desired.

### DISCLOSURE

The multi-layer metal article includes a metal base formed from a first metal and at least one interlayer formed on a surface of the metal base. The at least one interlayer is formed from a second metal having a greater hardness than a hardness of the first metal, thus increasing the hardness of the overall multi-layer metal article when compared against the hardness of just the metal base. An outer coating layer may then be coated on the at least one interlayer. As a non-limiting example, the outer coating layer may be a scratch-resistant material, thus increasing both the hardness and scratch resistance of the overall multi-layer metal article when compared against those of just the metal base. The outer coating layer may be transparent, partially transparent or opaque. Similarly, the at least one interlayer may be transparent, partially transparent or opaque.

It should be understood that the at least one interlayer may be formed on the metal base using any suitable method, for example, but not limited to, physical vapor deposition, chemical vapor deposition, hybrid physical-chemical vapor deposition, ion plating, thin film deposition, ion beam-assisted deposition, wet plating or electroplating. Similarly, it should be understood that the outer coating layer may be coated on the at least one interlayer using any suitable method, for example, but not limited to, physical vapor deposition, chemical vapor deposition, hybrid physical-chemical vapor deposition, ion plating, thin film deposition, ion beam-assisted deposition, wet plating or electroplating.

These and other features of the present subject matter will become readily apparent upon further review of the following specification.

### BRIEF DESCRIPTION OF THE DRAWINGS

FIG. 1 is a side sectional view of a multi-layer metal article.

FIG. 2 is a side sectional view of a metal base of the multi-layer metal article.

FIG. 3 is a side sectional view of the metal base of FIG. 2 with an interlayer formed thereon.

Similar reference characters denote corresponding features consistently throughout the attached drawings.

### BEST MODE(S)

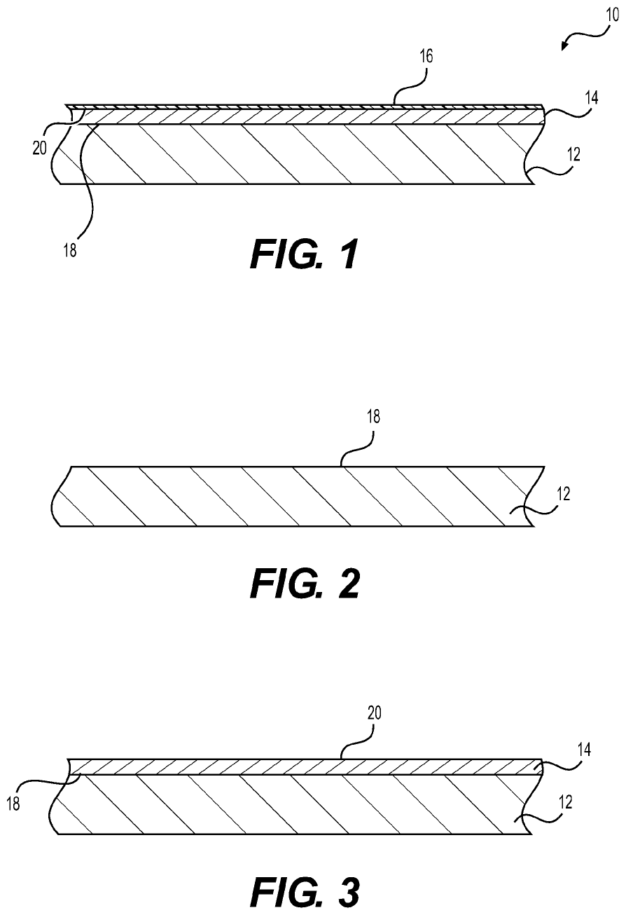

As shown in FIGS. 1-3, the multi-layer metal article 10 includes a metal base 12 formed from a first metal and at least one interlayer 14 formed on an upper surface 18 of the metal base 12. FIG. 2 illustrates the metal base 12 alone and, as shown in FIG. 3, at least one interlayer 14 is then formed on upper surface 18 of metal base 12 in a manner that will be described in greater detail below. In FIGS. 1 and 3 only a single interlayer 14 is illustrated, although it should be understood that any suitable number of layers may be formed, one on top of the other. Further, it should be understood that layers of different materials may form the at least one interlayer 14; i.e., the at least one interlayer may be composed of a first layer of one material, a second layer of another material, etc. The at least one interlayer 14 is formed from at least one second metal having a greater hardness than a hardness of the first metal, thus increasing the hardness of the overall multi-layer metal article 10 when compared against the hardness of just the metal base 12.

As seen in FIG. 1, an outer coating layer 16 may then be coated on an upper surface 20 of the at least one interlayer 14. As a non-limiting example, the outer coating layer 16 may be a scratch-resistant material, thus increasing both the hardness and scratch resistance of the overall multi-layer metal article 10 when compared against those of just the metal base 12. The outer coating layer 16 may be transparent, partially transparent or opaque. Similarly, the at least one interlayer 14 may be transparent, partially transparent or opaque. It should be understood that the outer coating layer 16 may be made from any suitable material, for example, but not limited to, polycarbonate, acrylic, mineral glass, sapphire crystal, tempered glass, titanium, diamond, silicon carbide, boron nitride, carbon, ceramic or the like. It should be further understood that the outer coating layer 16 may be selected dependent upon a desired appearance of the multi-layer metal article 10, thus, outer coating layer 16 may have, for example, a matte appearance, a semi-matte appearance, a shiny surface or the like. As a non-limiting example, outer coating layer 16 may be a scratch-resistant coating having a medium gloss measuring 10 GU.

It should be further understood that the at least one interlayer 14 may be formed on the metal base 12 using any suitable method, for example, but not limited to, physical vapor deposition, chemical vapor deposition, hybrid physical-chemical vapor deposition, ion plating, thin film deposition, ion beam-assisted deposition, wet plating or electroplating. Similarly, it should be understood that the outer coating layer 16 may be coated on the at least one interlayer 14 using any suitable method, for example, but not limited to, physical vapor deposition, chemical vapor deposition, hybrid physical-chemical vapor deposition, ion plating, thin film deposition, ion beam-assisted deposition, wet plating or electroplating. Dependent upon the particular type of article being formed, the at least one interlayer 14 may have any suitable thickness. As a non-limiting example, a layer of the second metal formed on metal base 12 may have a thickness ranging between 0.5 μm to 4.0 μm.

Jewelry, decorative articles and the like are often formed from precious metals, such as gold, silver, platinum and the like. These metals, particularly when of high purity, tend to be soft metals. Thus, the at least one interlayer 14 is formed on the metal base 12, which is formed from such a metal, in order to increase its hardness. As a non-limiting example, the first metal forming metal base 12 may have a Mohs hardness less than or equal to 4.5-6, and the second metal forming the at least one interlayer 14 may have a Mohs hardness greater than 6.

However, it should be understood that metal base 12 may be formed from any suitable type of metal. Examples of metals which may be used for metal base 12 include, but are not limited to, gold, silver, platinum, brass, bronze, nickel, rhodium, platinum, palladium, iridium, osmium, rhenium, ruthenium, beryllium, indium, tellurium, bismuth, lead, tin, zinc, aluminum, copper, brass, bronze, nickel, indium, carbon and alloys, ceramics and combinations thereof. Similarly, it should be understood that the at least one interlayer 14 may be formed from any suitable type of metal. Examples of metals which may be used for the at least one interlayer 14 include, but are not limited to, rhodium, platinum, palladium, iridium, osmium, rhenium, ruthenium, germanium, beryllium, indium, gallium, tellurium, bismuth, mercury, stainless steel, hardened steel, aluminum, chromium, chromium nitride, carbon, tungsten, tungsten carbide, tantalum carbide, cadmium, nickel, tin, lead, zinc, copper, titanium, titanium nitride, titanium aluminum nitride, aluminum chromium nitride, carbon and alloys, ceramics and combinations thereof.

It is to be understood that the multi-layer metal article and method of making the same are not limited to the specific embodiments described above, but encompasses any and all embodiments within the scope of the generic language of the following claims enabled by the embodiments described herein, or otherwise shown in the drawings or described above in terms sufficient to enable one of ordinary skill in the art to make and use the claimed subject matter.

1. A multi-layer metal article, comprising:
a metal base comprising a first metal;
at least one interlayer formed on a surface of the metal base, the at least one interlayer comprising a second metal having a greater hardness than a hardness of the first metal; and
an outer coating layer coated on the at least one interlayer.

2. The multi-layer metal article as recited in claim 1, wherein said first metal is selected from the group consisting of gold, silver, platinum, brass, bronze, nickel, rhodium, platinum, palladium, iridium, osmium, rhenium, ruthenium, beryllium, indium, tellurium, bismuth, lead, tin, zinc, aluminum, copper, brass, bronze, nickel, indium, carbon and alloys, ceramics and combinations thereof.

3. The multi-layer metal article as recited in claim 1, wherein said second metal is selected from the group consisting of rhodium, platinum, palladium, iridium, osmium, rhenium, ruthenium, germanium, beryllium, indium, gallium, tellurium, bismuth, mercury, stainless steel, hardened steel, aluminum, chromium, chromium nitride, carbon, tungsten, tungsten carbide, tantalum carbide, cadmium, nickel, tin, lead, zinc, copper, titanium, titanium nitride, titanium aluminum nitride, aluminum chromium nitride, carbon and alloys, ceramics and combinations thereof.

4. The multi-layer metal article as recited in claim 1, wherein said at least one interlayer is at least partially transparent.

5. The multi-layer metal article as recited in claim 1, wherein said at least one interlayer is opaque.

6. The multi-layer metal article as recited in claim 1, wherein said outer coating layer comprises a scratch-resistant material.

7. The multi-layer metal article as recited in claim 1, wherein said outer coating layer is at least partially transparent.

8. The multi-layer metal article as recited in claim 1, wherein said outer coating layer is opaque.

9. A method of making a multi-layer metal article, comprising the steps of:
forming at least one interlayer on a surface of a metal base, wherein the metal base comprises a first metal and the at least one interlayer comprises a second metal, the second metal having a greater hardness than a hardness of the first metal; and
coating an outer coating layer on the at least one interlayer.

10. The method of making a multi-layer metal article as recited in claim 9, wherein the step of forming the at least one interlayer on the surface of the metal base comprises a deposition technique selected from the group consisting of physical vapor deposition, chemical vapor deposition, hybrid physical-chemical vapor deposition, ion plating, thin film deposition, ion beam-assisted deposition, wet plating and electroplating.

11. The method of making a multi-layer metal article as recited in claim 9, wherein the step of coating the outer coating layer on the at least one interlayer comprises a coating technique selected from the group consisting of physical vapor deposition, chemical vapor deposition, hybrid physical-chemical vapor deposition, ion plating, thin film deposition, ion beam-assisted deposition, wet plating and electroplating.

12. The method of making a multi-layer metal article as recited in claim 9, wherein said first metal is selected from the group consisting of gold, silver, platinum, brass, bronze, nickel, rhodium, platinum, palladium, iridium, osmium, rhenium, ruthenium, beryllium, indium, tellurium, bismuth, lead, tin, zinc, aluminum, copper, brass, bronze, nickel, indium, carbon and alloys, ceramics and combinations thereof.

13. The method of making a multi-layer metal article as recited in claim 9, wherein said second metal is selected from the group consisting of rhodium, platinum, palladium, iridium, osmium, rhenium, ruthenium, germanium, beryllium, indium, gallium, tellurium, bismuth, mercury, stainless steel, hardened steel, aluminum, chromium, chromium nitride, carbon, tungsten, tungsten carbide, tantalum carbide, cadmium, nickel, tin, lead, zinc, copper, titanium, titanium nitride, titanium aluminum nitride, aluminum chromium nitride, carbon and alloys, ceramics and combinations thereof.

14. The method of making a multi-layer metal article as recited in claim 9, wherein said at least one interlayer is at least partially transparent.

15. The method of making a multi-layer metal article as recited in claim 9, wherein said at least one interlayer is opaque.

16. The method of making a multi-layer metal article as recited in claim 9, wherein said outer coating layer comprises a scratch-resistant material.

17. The method of making a multi-layer metal article as recited in claim 9, wherein said outer coating layer is at least partially transparent.

18. The method of making a multi-layer metal article as recited in claim 9, wherein said outer coating layer is opaque.
